(19) United States
(12) Patent Application Publication
(10) Pub. No.: US 2003/0041300 A1
(43) Pub. Date: Feb. 27, 2003

(54) Universal device for processing Reed-Solomon forward error-correction encoded messages

(75) Inventors: Geoffrey F. Burns, Ridgefield, CT (US); Benjamin Bouyssou, Issy les Moulineaux (FR)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/935,894

(22) Filed: Aug. 23, 2001

(51) Int. Cl. H03M 13/00

(52) U.S. Cl. 714/784

(57) ABSTRACT

A system and method for implementing a universal Reed-Solomon (R-S) encoder and decoder that can process variable sized data blocks and variable sized Galois fields in a same hardware device. The Galois field operators for multiplication, scale, inversion, and addition are each implemented as symbol-width bit-logic arrays that correspond to a maximum symbol width, and for symbols having smaller widths, the extraneous bits are unused. The present invention allows for selection of a multitude of operational data word widths based on a computer-controlled selection port on the hardware device.

### FIELD OF THE INVENTION

This invention relates to the field of data error correction in communications systems, and more particularly to a device and method for correcting data errors in electronic signals using variable-sized Galois fields and variable-sized symbol widths.

### BACKGROUND OF THE INVENTION

In data communications systems, various error phenomena can destructively alter data content of a message. To correct such errors, a data block is typically encoded prior to transmission by generating and transmitting an appended descriptive code word, which can be used in the accurate decoding and reconstruction of a damaged data block at a destination receiver. Widely used error-correction techniques, such as that used in a Reed-Solomon (R-S) encoder, are characterized by a fixed-sized data block that is processed using a predetermined polynomial. From this process, a resultant parity data block is created and appended to the processed data block, and the appended block is transmitted as a message.

Since the processing polynomial, data block size, and symbol size are known to all elements of the communications system, upon receipt, a syndrome is calculated from the code word. The syndrome can then be used to indicate the locations of any errors in the received data block, which can then be corrected. For better understanding of the R-S error-correction process, see U.S. Pat. No. 6,061,826 to Thirumoorthy, et al, which teaches the use a R-S encoder that uses Galois Fields to encode the data of a fixed size data block. A significant drawback of such applications using Reed-Solomon is that the encoding must be customized to each specific application, both in the size of the data blocks and the size of the Galois fields. Thus, different applications would require unique construction of the polynomials and the encode/decode processes.

Since in software R-S implementations, computational delays are typically associated with repetitive XOR processing of the data blocks, software solutions are better suited to lower data-rates and are not typically used in high data-rate communications systems. For high data-rate systems, R-S algorithms are optimally implemented in hardware, such as in programmable logic arrays (PLAs). These PLAs accept data at an input port of the device and provide an “instantaneous” processed output at an output port. Given the “customized” nature of a particular R-S algorithm, programmed devices cannot be used for different applications, and there exists a need for a universal encoder/decoder that can be used for different sized data blocks and different sized Galois fields.

### SUMMARY

In a preferred embodiment of the present invention, a system and method is provided for implementing a universal Reed-Solomon (R-S) encoder and decoder that can process variable-sized and variable-symbol-width data blocks using variable-sized Galois fields. With such a universal R-S decoder, all anticipated code words can be accommodated in a single chip, rather than building a fixed decoder for each codeword. In the preferred embodiment, a multitude of logical operators associated with the variable sized fields are embedded in a programmable logic array. In alternate embodiments, methods for implementing the process in retrievable software modules are presented.

The universality of the hardware embodiment allows for the implementation of relaxed R-S encoders for lower-cost and more error-tolerant applications, while allowing for the implementation of more sophisticated and powerful processing for less error-tolerant applications using the same hardware device. The Galois field operators for multiplication, scale, inversion, and addition are each implemented as symbol width bit logic arrays that corresponds to a maximum symbol width and a maximum-sophistication processor. For symbols having smaller widths, the additional bits are unused. This allows for selection of one of a multitude of widths for data symbols based on computer-controlled selection port on the hardware device.

### BRIEF DESCRIPTION OF THE DRAWINGS

FIG. 1 shows a block diagram of typical processing elements of a conventional communications system.

FIG. 2 shows a table of conventional R-S decoder algorithm parameters for different symbol sizes in representative communications standards.

FIG. 3 shows a block diagram of a universal Reed-Solomon decoder according to a preferred embodiment of the present invention.

FIG. 4 shows an exemplary scalar-accumulate operator for syndrome calculation which is used in the block diagram shown in FIG. 3.

FIG. 5 shows an exemplary configurable α⁶ scalar. FIG. 6 shows a programmable processor implemented according to an embodiment of the present invention.

FIG. 7 shows a configurable GF tuple-tuple multiplier according to an embodiment of the present invention.

FIG. 8 shows a row of the configurable multipliers shown in FIG. 7.

FIG. 9 shows a configurable multiplier array stage for the sixth multiplicand bit B₆.

FIG. 10 shows an exemplary circuit for implementing the array stage A*B₁ according to an embodiment of the present invention.

### DETAILED DESCRIPTION OF THE INVENTION

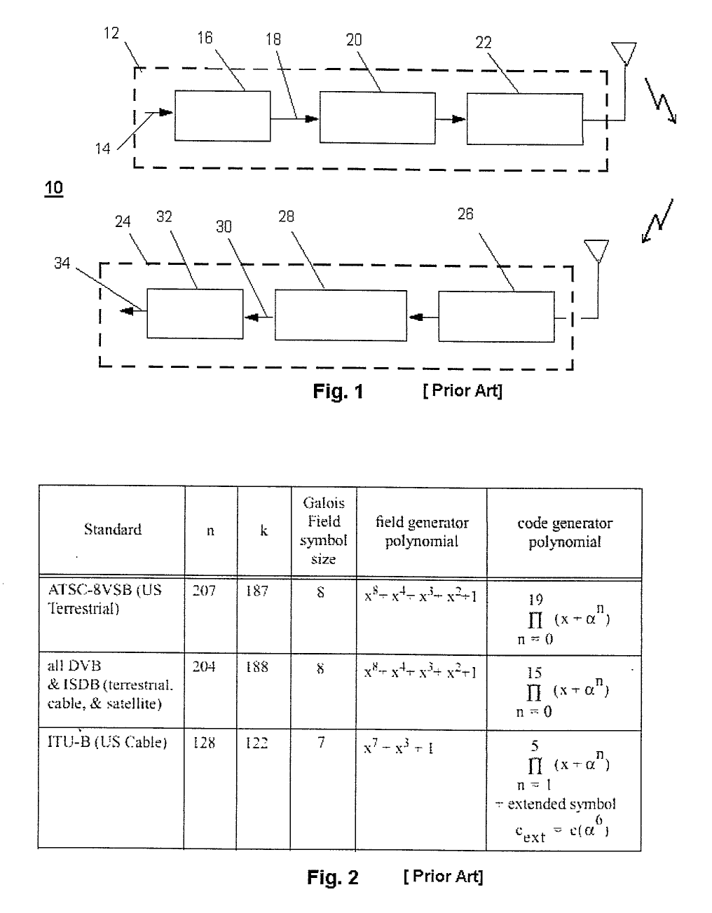

FIG. 1 shows a block diagram of typical processing elements of a conventional communications system 10. In a typical transmitting apparatus 12 using a Reed-Solomon (R-S) error-correction processor, a serial data signal 14 is presented to an input of a R-S data encoder 16, which calculates a code word comprised of parity symbols representing data signal 14. The parity symbols are appended to data signal 14 to produce an encoded output signal 18, which is sent to a modulator 20 and a transmitter 22 for over-the-air transmission to a remote receiver apparatus 24.

After reception in receiver element 26 of receiver apparatus 24, the signal is demodulated in demodulator 28 to extract a serial data signal 30. Due to communications path effects, serial data signal 30 can now contain a multitude of random errors, which need to be corrected to restore the integrity of the message. By processing serial data signal 30 with a duplicate R-S processor in R-S decoder 32, a code word can be calculated for the received signal. By calculating the most-likely transmitted code word from the transmitting apparatus, decoder 32 can identify any errors in serial data signal 30 by specific location in the data bit stream and can corrected them accordingly. Resulting serial data signal 34 then becomes a duplicate of the original data signal 14.

Occasionally, however, the number of errors can exceed the correction capability of the R-S decoder, and other means would be required to satisfactorily complete the communication of the message, such as retransmission, for example. However, such means are beyond the scope of the present invention, which addresses only those messages that can be corrected using the selected R-S methods. The forgoing has been simplified for teaching purposes, and the reader should understand that the encoding and decoding algorithms are quite sophisticated.

For example, a R-S coding and decoding algorithm is organized around polynomials of Galois Field symbols, as is known in the art. In such a system, a predetermined sized data bit stream signal 14 is partitioned into packets of k symbols, with each symbol having a bit count m that is equal to a Galois field symbol size. Encoder 16 interprets the data bit stream signal 14 as a k-symbol polynomial over Galois Field (GF) GF(2^{m}), where m is the number of bits per symbol in the particular Galois Field. After processing, encoder 16 appends a number of parity symbols to the input serial data signal 14 to give a new data block size of n symbols. Although a system designer can arbitrarily use any polynomial for a particular R-S communications system, there exist a finite set of unique polynomials that are optimized for a given symbol size and these polynomials have become widely used in communications industry standards.

FIG. 2 shows a table of conventional R-S decoder algorithm parameters for different symbol sizes in representative communications standards. As can be seen from the table in FIG. 2, the code block length of n symbols, having k data symbols, and Galois Field varies across the standards. The field generator polynomials shown in FIG. 2 are represented such that the superscripted number represents a specific bit location (1 through 8) in a symbol, with bit 1 being the least significant bit and the first bit in a serial bit stream.

By selecting one of the R-S standards shown in the table of FIG. 2, a hardware design can be implemented in a PLA or preferably a high-density ASIC. A multitude of logical arithmetic elements, such as scalars, multipliers, dividers, etc. can be defined by a set of key Galois field arithmetic elements. These arithmetic elements are imbedded in the ASIC and interconnected to produce one of the desired mathematical and Boolean operators according to the codes described in FIG. 2.

However, when a specific R-S application device has heretofore been applied to applications having different data block sizes and/or different symbol sizes, the R-S processor has failed due to the incompatibilities. Some of these incompatibilities relate to performing valid mathematical operations using different sized Galois field operators together and others relate to different mathematical configurations attempting to perform operations for which an embedded processor was inadequate. An example of the former is a multiplication of a seven bit by an eight-bit symbol and determining a valid width for the resultant.

An example of the latter is the multiplication of exponential numbers, wherein a binary, or tuple, number representation operator, which are ideal for performing addition and subtraction, are not well suited to perform such a multiplication of exponents. A preferable alternative operator would be one configured for a power number system, which would simply add the exponents. Thus, from the above it becomes obvious that an optimized universal system would preferably have a group of such differently configured operators and the ability to appropriately interconnect those operators as desired.

The only operator that can be directly reused across different Galois fields is an addition operator, which simply bit-wise exclusively ORs (XOR) the input terms to produce a sum. For Galois fields having different sizes, this operation still provides a valid result. However, other operators, such as multiplication, scale (multiply by a constant), and inversion cannot easily be used across number systems or Galois field sizes, and heretofore, these operations were typically realized using look up tables which mapped boolean relationships between an input and an output port, as is known in the art.

Thus, according to the present invention, a set of key Galois field arithmetic elements are created that can allow multiple Galois field processors to be implemented in a same hardware device, such as the ASIC. In an exemplary decoder architecture, a tuple-tuple notation can be selected for all two-operation elements. Thus, by incorporating a configurable tuple-tuple multiplier, a tuple inversion element, and a set of tuple scalers in the same hardware ASIC, a Reed-Solomon Decoder capable of decoding GF(2⁸) and FG(2⁷) can be realized. Expansion of the following techniques can be used to implement a universal R-S Decoder.

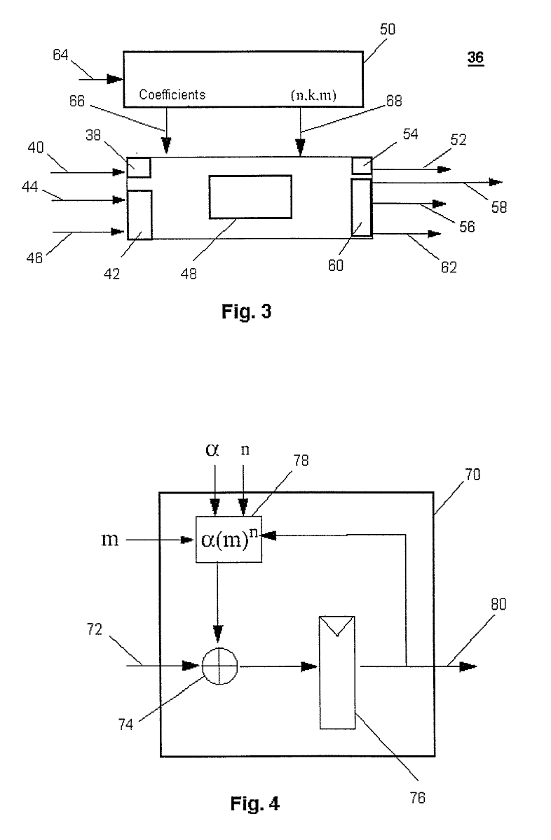

FIG. 3 shows a block diagram of a programmable universal R-S decoder 36 according to a preferred embodiment of the present invention. An exemplary (n,k) R-S decoder 36 over a Galois field GF(2^{m}) preferably is implemented in a single high-density integrated circuit and includes a data signal input block 38 for receiving an input data signal 40 and an input data timing control block 42 for receiving data control signals, such as a symbol strobe 44 and a packet start signal 46. An R-S processor block 48, which is programmed by a configuration controller 50, operates on the data stream and provides either a corrected data signal 52 at an output port 54 with appropriate timing control signals, such as strobe signal 56 and packet start signal 58, at an output control port 60 or provides an error signal 62, indicating that the data block could not be corrected.

Prior to receipt of the above data input, configuration controller 50 receives a configuration command signal 64 from a master controller (not shown), such as a computing device or a user external I/O port, and loads a plurality of scalar coefficient signals 66 and a plurality of configuration control logic signals 68 into corresponding control blocks for use by R-S control processor 48. The use of scalar coefficient signals 66 could be used to enable or disable a particular mathematical operator in order to implement a selected operating polynomial. Similarly, configuration control logic signals 68 could be used to logically select particular arithmetic operator interconnection paths depending on the symbol size, data block size, and parity block size.

As a symbol is received, the individual data bits of the symbol are routed to a unique bit path for the decoding operations. Each data bit will be processed by a multitude of the uniquely-scaled mathematical operators in order to produce a set of syndrome or parity symbols for locating and correcting any errors.

FIG. 4 shows an exemplary scalar-accumulate operator 70 for syndrome calculation which is used in the block diagram shown in FIG. 3. Scalar-accumulate operator 70 multiplies one Galois field symbol by a Galois field constant, which is determined by a particular one of the plurality of scalar coefficient signals 66 and configuration logic control signals 68 that were previously loaded by configuration controller 50, (i.e. m, n, and α.) An input bit symbol signal 72 is routed to an adder 74 which sums (i.e., bit-by-bit XOR) the input signal 72 with a scaled feedback signal that is derived from storage element 76, such as a register, and scalar 78 to produce a resultant output signal 80. Such a store-and-accumulate operator is well known in the art, but typically without the configuration control logic signals.

A scaling factor provided by configured scalar 78 can be a positive or negative number or zero. An effective coefficient of zero eliminates that bit-term from a polynomial. For a parallel data path having one such scalar for each data bit, each bit is processed by a uniquely-scaled mathematical operator depending on the polynomial being implemented.

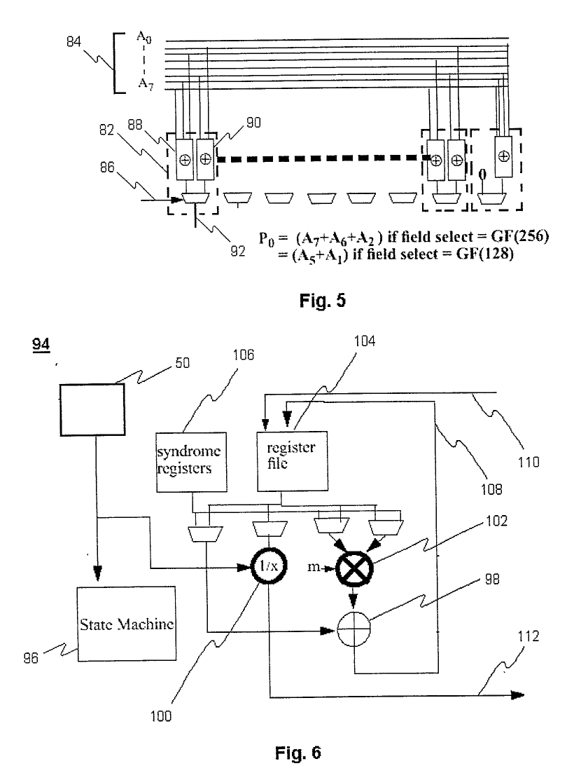

FIG. 5 shows an exemplary configurable α⁶ scalar 82 for GF(256) and GF(128), wherein an input signal A₀₋₇ 84 is multiplied by α⁶ based on the logical state of a field select gating signal 86. Scalar 82 is composed of two logical operators, a first gate 88 for GF(256) and a second gate 90 for GF(128) (i.e. 8 and 7 bit widths, respectively.) First gate 88 is electrically connected to data bit lines A₂, A₆, and A₇ and second gate 90 is electrically connected to data bit lines A₁ and A₅. When field select gating signal 86 is in a first logical state, a logical high, for example, an output signal (i.e. P₀=A₂+A₆+A₇) of first gate 88 is passed through to scalar output node 92. When signal 86 is in the opposite logical state, an output signal (i.e. P₀=A₁+A₅) of second gate 90 is passed to node 92. In a similar manner, any polynomial operator can be constructed, to emulate the field and code generator polynomials shown in FIG. 2.

Thus, in combining the logical selection detail shown in FIG. 5 to the syndrome block diagram shown in FIG. 4, FIG. 6 shows a programmable processor 94 implemented according to an embodiment of the present invention. Programmable processor 94 is controlled by configuration controller 50, and includes a state machine 96 for controlling the timing of the operations, a summing operator 98 (bit-by-bit XOR), an inversion operator 100, and a multiplier operator 102. All of the preceding elements (96-102) are configurable in accordance with the foregoing discussion, with each being configured according to the size of the Galois field.

Additionally, a storage register file 104, comprised of multiple bit-storage elements 76 in FIG. 4 for storing feed back signal 108 and a syndrome accumulation register 106 for storing the results from the syndrome calculator in FIG. 4 combine to process a received data signal to produce an error-corrected output signal 112. By configuring and connecting a multitude of such programmable processor as shown in FIG. 6, a R-S decoder can be realized.

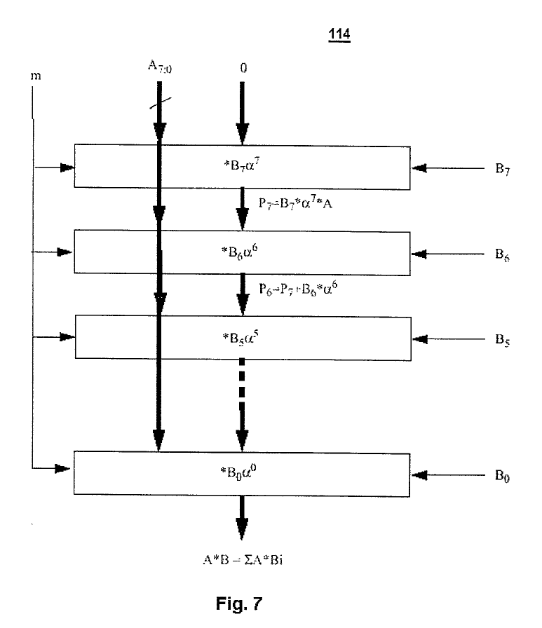

FIG. 7 shows a configurable GF tuple-tuple multiplier 114 according to an embodiment of the present invention, where m signal selects the Galois field of the two operands. Each bit of multiplicand B₀₋₇ enables a scalar that multiplies multiplicand A₀₋₇ by a scalar corresponding to the significance of the particular bit of B₀₋₇. For example, B₇ enables A to be scaled by the constant α⁷. Successive addition of the scalar products of A and B₁ realizes the multiplication.

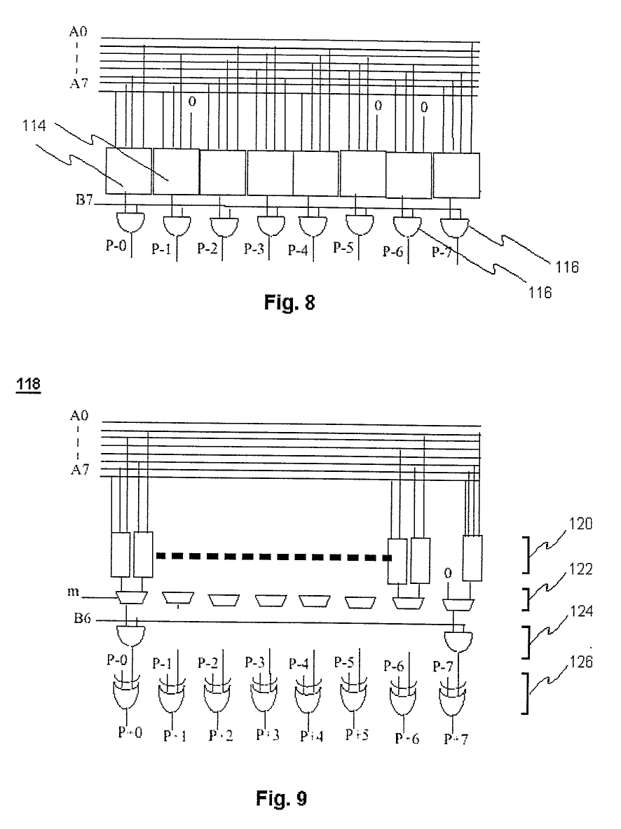

FIG. 8 shows a row of the configurable multipliers shown in FIG. 7, for the exemplary B7 multiplication shown in FIG. 6. Bits from A₀₋₇ are mapped to XOR circuits 116 that are connected according to the Boolean relationship between the product bit and the input A₀₋₇.

FIG. 9 shows a configurable multiplier array stage 118 for the 6^{th} multiplicand bit B₆. The XOR circuits 120 are connected to bits in A₀₋₇ according to the Boolean relationships between each partial product bit and the input A. Since this relationship changes between GF(128) and GF(256), a row of multiplexers 122 select one of the two possibilities according to the Galois field configuration value m. The AND gate row 124 enables injection of the product α⁶*A into the array. The row of XOR gates 126 add the values from α⁷*A to the output of the enabled scalar stage.

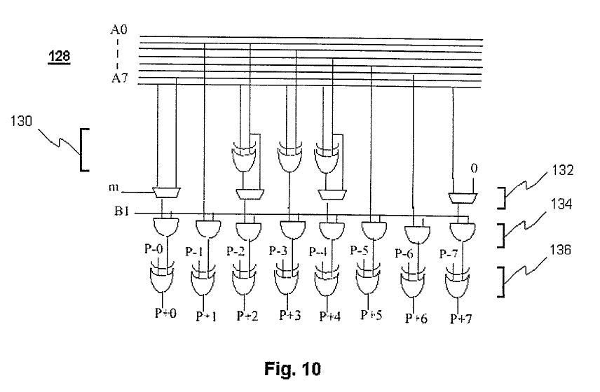

FIG. 10 shows an exemplary circuit 128 for implementing the array stage A*B₁ according to an embodiment of the present invention. The configurable XOR circuits 130 are reduced due to the simple implementation of a truth table, which is mostly a shift operation. The rows of multiplexers 132, AND gates 134, and XOR gates 136 perform the same enable and partial product propagation shown in FIG. 9.

From the foregoing, by a defining a set of key Galois field arithmetic elements that allow multiple Galois field processors to be implemented in an integrated circuit, a universal R-S decoder can be realized. Through the selection of logical elements and selective interconnections of those elements by a gating configuration control block, a multitude of error-locating generator polynomials can be implemented in the IC, which allow for use of Galois fields and operators having different sizes. Then a particular polynomial and data width characteristics can be selected from an abbreviated list of polynomials and data widths to implement a specific R-S that is appropriate for a unique communications architecture.

The Galois field operators for multiplication, scale, inversion, and addition can be each implemented as symbol width bit logic arrays that corresponds to a maximum symbol width. Further, for symbols having smaller widths, the additional bits are unused. This allows for selection of operational data word widths based on computer-controlled selection port on the hardware device. With such an implementation, a data block can be presented at an input port of the IC and, if the error count is below a predetermined threshold number of errors, a corrected data block can be outputted to a next receiver processing element in real time. This offers distinct speed advantages over that of an R-S software implementation in that iterative operations, such as add-and-accumulate, can be performed nearly instantaneously in hardware.

Numerous modifications to and alternative embodiments of the present invention will be apparent to those skilled in the art in view of the foregoing description. Accordingly, this description is to be construed as illustrative only and is for the purpose of teaching those skilled in the art the best mode of carrying out the invention. Details of the embodiments may be varied without departing from the spirit of the invention, and the exclusive use of all modifications which come within the scope of the appended claims is reserved.

What is claimed is:

1. A universal Reed-Solomon (R-S) decoding integrated circuit (IC) for correcting errors in a received data bit stream signal having a selectable data width and a selectable data block size, comprising:
a configuration control means;
a data input means;
a configurable computational processing means, further comprising:
a plurality of configurable arithmetic-operation blocks;
a plurality of configurable interconnections between the configurable arithmetic-operation blocks; and
an error identification means;
an error correction means; and
a data output means.

2. The universal R-S decoding IC according to claim 1, wherein the configuration control means comprises a plurality of user input parameters.

3. The universal R-S decoding IC according to claim 2, wherein the configuration control means comprises a means for implementing one data width configuration from a plurality of data width configurations.

4. The universal R-S decoding IC according to claim 2, wherein the configuration control means comprises a means for implementing one data block size from a plurality of data block sizes.

5. The universal R-S decoding IC according to claim 2, wherein the configuration control means comprises a means for inputting scalar coefficients.

6. The universal R-S decoding IC according to claim 1, wherein each one of the plurality of configurable arithmetic-operation blocks further comprises a plurality of logical circuit gates needed to implement one or more of the mathematical operations from the group consisting of addition, multiplication, and inversion.

7. The universal R-S decoding IC according to claim 6, wherein each one of the a plurality of configurable arithmetic-operation blocks has a configuration control receiving means, a data signal input means, a computation means, an error-correction means, and a data signal output means.

8. The universal R-S decoding IC according to claim 7, wherein the configurable computational processing means is configured by the loading of one or more coefficients from the configuration control means.

9. The universal R-S decoding IC according to claim 1, wherein the configurable computational processing means is characterized in that hardware for a first Galois field can perform mathematical operations on a second Galois field.

10. The universal R-S decoding IC according to claim 1, wherein the error identification mean computes the error location and magnitude in an inputted data block.

11. An integrated circuit (IC) for correcting data errors using a Reed-Solomon (R-S) decoder, comprising at least a first selectable computational processor and a second selectable computational processor and a configuration control means for selecting one and only one of the computational processors.

12. The IC according to claim 11, wherein the first and the second computational processors each comprise a data signal input means, a computation means, an error-correction means, and a data signal output means.

13. The IC according to claim 12, wherein the first computational processor has a plurality of mathematical functions required to implement a first Reed-Solomon decoder for a data signal having a first width, and the second computational processor has a plurality of mathematical functions required to implement a second Reed-Solomon decoder for a data signal having a second width.

14. The IC according to claim 13, wherein the first width comprises 8 bits and the second width comprises 7 bits.

15. The IC according to claim 11, wherein the configuration control means further comprises:
a user command input means;
a first selection means for logically selecting one or more arithmetic functional blocks from a plurality of arithmetic functional blocks to realized the Reed-Solomon decoder; and
an outputting means for configuring the IC according to the selection means.

16. A method for selecting a unique set of electronic decoder elements from a plurality of decoder elements in an integrated circuit (IC) to implement one Reed-Solomon Decoder from a plurality of possible Reed-Solomon (R-S) decoders, comprising the steps of:
a) loading a Galois field symbol size parameter into the IC;
b) loading a plurality of multiplier coefficients into the IC;
c) loading a data block size parameter n into the IC; and
d) loading a parity symbol width size parameter into the IC.

17. The method according to claim 16, wherein the Galois field symbol size parameter comprises 7 or 8 bits.

18. The method according to claim 16, wherein the plurality of multiplier coefficients are characterized in that a particular R-S polynomial is implemented in the IC.

19. A method for correcting data errors in a serial data block using an integrated circuit (IC) having a configurable Reed-Solomon (R-S) error-correction decoder, comprising the steps of:
a) loading a plurality of configuration parameters into the IC;
b) inputting a first data block into the IC;
c) processing the data block in the configured IC to identify and enumerate any data errors in the data block;
d) outputting a corrected data block if the number of errors are below a predetermined threshold; or
e) outputting an error signal if the number or errors exceeds the predetermined threshold.

20. The method according to claim 19, wherein the data block comprises a portion relating to data and a portion relating to parity checking.
